(19) United States
(12) Patent Application Publication
(10) Pub. No.: US 2026/0142619 A1
(43) Pub. Date: May 21, 2026

(54) Oscillator circuit having phase-noise decreasing mechanism

(71) Applicant: REALTEK SEMICONDUCTOR CORPORATION, HSINCHU (TW)

(72) Inventor: YUNG-CHUNG CHEN, HSINCHU (TW)

(21) Appl. No.: 19/388,470

(22) Filed: Nov. 13, 2025

(30) Foreign Application Priority Data
Nov. 15, 2024 (TW) 113144152

(51) Int. Cl. H03B 5/12

(52) U.S. Cl. CPC H03B 5/1212; H03B 5/1228; H03B 5/1265; H03B 2200/009

(57) ABSTRACT

An oscillator circuit having phase-noise decreasing mechanism is provided. An inductor circuit includes an inductor coil surrounding a central area and coupled between oscillating output terminals. A capacitor circuit is coupled between the oscillating output terminals. A cross-coupled CMOS circuit is disposed between the inductor circuit and the capacitor circuit to be coupled to the oscillating output terminals. A first wire and a second wire stretch along with an axis to traverse the central area to divide the central area into two sub areas. A first and a second source degeneration circuits are disposed at the second side of the inductor coil and are respectively disposed at two symmetrical sides of the axis. The first and the second source degeneration circuits respectively are coupled to the cross-coupled CMOS circuit through the first and the second wires.

### BACKGROUND OF THE INVENTION

### 1. Field of the Invention

The present invention relates to an oscillator circuit having a phase-noise decreasing mechanism.

### 2. Description of Related Art

Oscillator circuits, especially LC oscillator circuits, are circuits that include a capacitor circuit and an inductor circuit electrically coupled together and operate according to an oscillating activity. Oscillator circuits are widely used in circuits such as, but not limited to oscillators, filters, tuners, and mixers.

Oscillator circuits are often equipped with circuits that lower the phase noise. However, once these circuits are not disposed in a proper way, the asymmetrical configuration thereof degrades the ability to lower the phase noise.

### SUMMARY OF THE INVENTION

In consideration of the problem of the prior art, an object of the present invention is to supply an oscillator circuit having a phase-noise decreasing mechanism.

The present invention discloses an oscillator circuit having phase-noise decreasing mechanism that includes an inductor circuit, a capacitor circuit, a cross-coupled CMOS circuit, a first wire, a second wire, a first source degeneration circuit and a second source degeneration circuit. The inductor circuit includes an inductor coil surrounding a central area, wherein the inductor coil is electrically coupled between a pair of oscillating output terminals. The capacitor circuit is electrically coupled between the oscillating output terminals. The cross-coupled CMOS circuit is disposed at a first side of the inductor coil and between the inductor coil and the capacitor circuit to be electrically coupled to the pair of oscillating output terminals. The first wire and the second wire stretch from the first side of the inductor coil along with an axis and traverse the central area to a second side of the inductor coil opposite to the first side to divide the central area into two sub areas that are substantially symmetrical. The first source degeneration circuit and the second source degeneration circuit disposed at the second side of the inductor coil and at two symmetrical positions at two sides of the axis. The first source degeneration circuit is electrically coupled to the first wire and is further electrically coupled to the cross-coupled CMOS circuit through a first terminal, and the second source degeneration circuit is electrically coupled to the second wire and is further electrically coupled to the cross-coupled CMOS circuit through a second terminal.

These and other objectives of the present invention will no doubt become obvious to those of ordinary skill in the art behind reading the following detailed description of the preferred embodiments that are illustrated in the various figures and drawings.

### BRIEF DESCRIPTION OF THE DRAWINGS

FIG. 1 illustrates a circuit diagram of an oscillator circuit having a phase-noise decreasing mechanism according to an embodiment of the present invention.

FIG. 2 illustrates a layout diagram of the oscillator circuit in FIG. 1 according to an embodiment of the present invention.

### DETAILED DESCRIPTION OF THE PREFERRED EMBODIMENTS

An aspect of the present invention is to provide an oscillator circuit having a phase-noise decreasing mechanism that disposes a first wire and a second wire traversing a central area of an inductor coil in an inductor circuit and disposes a first source degeneration circuit and a second source degeneration circuit in a symmetrical way to be electrically coupled to a cross-coupled CMOS circuit through the first wire and the second wire. Such a configuration maintains a symmetrical electromagnetic field of the oscillator circuit and prevents the ability of the first source degeneration circuit and the second source degeneration circuit to lower the phase noise from degrading.

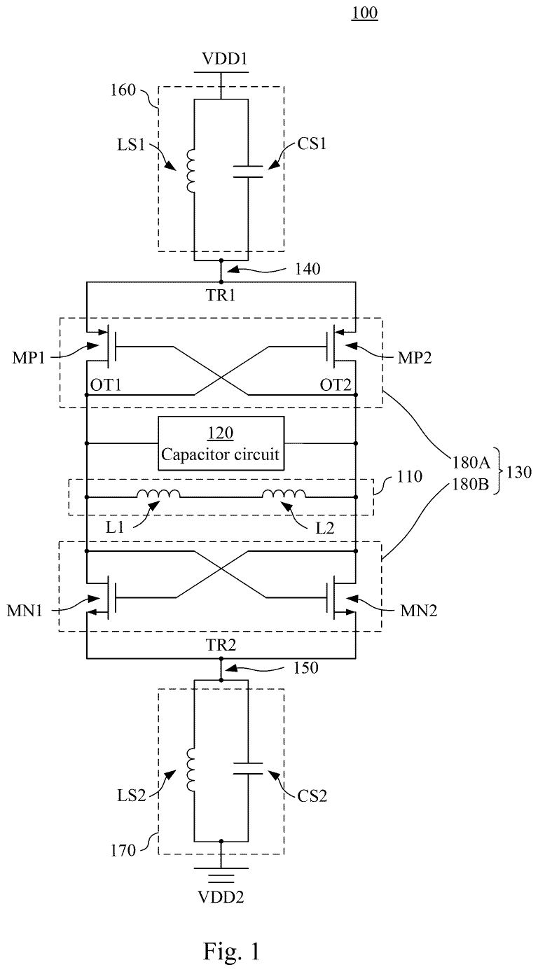

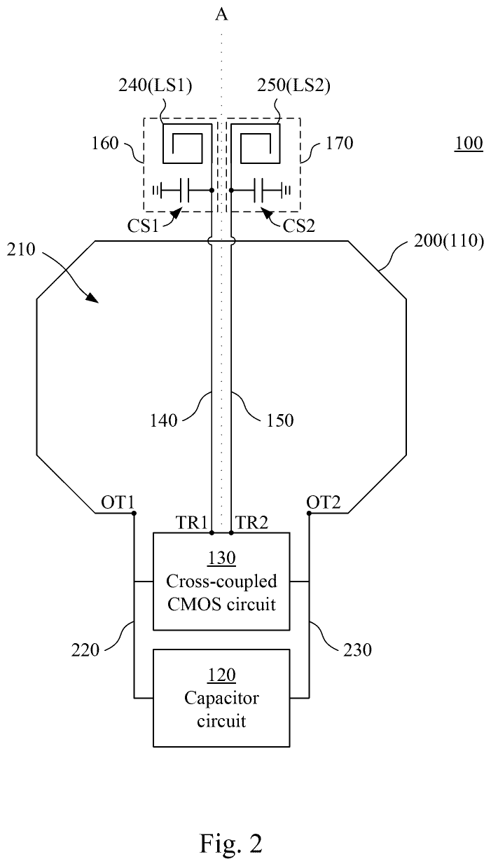

Reference is now made to FIG. 1 and FIG. 2 at the same time. FIG. 1 illustrates a circuit diagram of an oscillator circuit 100 having a phase-noise decreasing mechanism according to an embodiment of the present invention. FIG. 2 illustrates a layout diagram of the oscillator circuit 100 in FIG. 1 according to an embodiment of the present invention.

The oscillator circuit 100 operates according to a voltage difference between a first power voltage VDD1 and a second power voltage VDD2, and the second power voltage VDD2 is a ground level voltage in an embodiment. The oscillator circuit 100 includes an inductor circuit 110, a capacitor circuit 120, a cross-coupled CMOS circuit 130, a first wire 140, a second wire 150, a first source degeneration circuit 160 and a second source degeneration circuit 170.

The inductor circuit 110 is electrically coupled to a pair of oscillating output terminals OT1 and OT2. In FIG. 1, the inductor circuit 110 is illustrated to include an inductor L1 electrically coupled between the oscillating output terminal OT1 and an inductor L2 electrically coupled between the oscillating output terminal OT2. In practical implementation, the inductor circuit 110 can be implemented by an inductor coil 200 illustrated in FIG. 2 to be equivalent to the inductor L1 and the inductor L2 in FIG. 1, wherein the inductor coil 200 surrounds a central area 210.

The capacitor circuit 130 is electrically coupled between the oscillating output terminals OT1 and OT2. In FIG. 1, and FIG. 2, in order to simplify the drawing, the capacitor circuit 130 is illustrated to be a block. However, in an embodiment, the capacitor circuit 130 can be a switch capacitor array or a plurality of voltage-controlled capacitors (not illustrated in the figure), and selective include an output buffer circuit (not illustrated in the figure). In another embodiment, the capacitor circuit 130 includes at least one metal-oxide-metal capacitor (metal-oxide-metal capacitor; MOMCAP).

For the circuit diagram in FIG. 1, the cross-coupled CMOS circuit 130 includes a cross-coupled P-type transistor circuit 180A and a cross-coupled N-type transistor circuit180B.

The cross-coupled P-type transistor circuit 180A includes a first P-type transistor MP1 and a second P-type transistor MP2.

The first P-type transistor MP1 has a first drain electrically coupled to a first oscillating output terminal (e.g., the oscillating output terminal OT1) of the oscillating output terminals OT1 and OT2 and a first source electrically coupled to a first terminal TR1. The second P-type transistor MP2 has a second drain electrically coupled to a second oscillating output terminal (e.g., the oscillating output terminal OT2) of the oscillating output terminals OT1 and OT2 and a second source electrically coupled to the first terminal TR1. A first gate of the first P-type transistor MP1 is electrically coupled to the second oscillating output terminal (e.g., the oscillating output terminal OT2) and a second gate of the second P-type transistor MP2 is electrically coupled to the first oscillating output terminal (e.g., the oscillating output terminal OT1).

The cross-coupled N-type transistor circuit180B includes a first N-type transistor MN1 and a second N-type transistor MN2.

The first N-type transistor MN1 has a first drain electrically coupled to the first oscillating output terminal (e.g., the oscillating output terminal OT1) of the oscillating output terminals OT1 and OT2 and a first drain electrically coupled to a second terminal TR2. The second N-type transistor MN2 has a second drain electrically coupled to the second oscillating output terminal (e.g., the oscillating output terminal OT2) of the oscillating output terminals OT1 and OT2 and a second source electrically coupled to the second terminal TR2. A first gate of the first N-type transistor MN1 is electrically coupled to the second oscillating output terminal (e.g., the oscillating output terminal OT2) and a second gate of the second N-type transistor MN2 is electrically coupled to the first oscillating output terminal (e.g., the oscillating output terminal OT1).

In order to simplify the drawing, FIG. 2, the cross-coupled CMOS circuit 130 is illustrated to be a block in FIG. 2. For the layout diagram in FIG. 2, the cross-coupled CMOS circuit 130 is disposed at a first side of the inductor coil 200 and between the inductor coil 200 and the capacitor circuit 120 to be electrically coupled to the oscillating output terminals OT1 and OT2.

In an embodiment, the inductor coil 200 in FIG. 2 is electrically coupled to the capacitor circuit 120 and the cross-coupled CMOS circuit 130 through the oscillating output terminals OT1 and OT2 by using two extended wires 220 and 230 extending towards the first side of the inductor coil 200.

The first wire 140 and the second wire 150 stretch from the first side of the inductor coil 200 along with an axis A and traverse the central area 210 to a second side of the inductor coil 200 opposite to the first side to divide the central area 210 into two sub areas (not labeled in the figure) that are substantially symmetrical. It is appreciated that the term “substantially” means that the size and the shape of the sub areas may have a difference within a reasonable range and are not necessarily the same. In an embodiment, the first wire 140 and the second wire 150 are parallel to the extended wires 220 and 230.

The first source degeneration circuit 160 and the second source degeneration circuit 170 are disposed at the second side of the inductor coil 200. The first source degeneration circuit 160 and the second source degeneration circuit 170 are disposed at two symmetrical positions at two sides of the axis A.

The first source degeneration circuit 160 is electrically coupled to the first wire 140 and is further electrically coupled to the cross-coupled CMOS circuit 130 through the first terminal TR1. More specifically, the first source degeneration circuit 160 includes a first inductor LS1 and a first capacitor CS1 coupled in parallel through the first wire 140 between the first terminal TR1 and the first power voltage VDD1.

The second source degeneration circuit 170 is electrically coupled to the second wire 150 and is further electrically coupled to the cross-coupled CMOS circuit 130 through the second terminal TR2. More specifically, the second source degeneration circuit 170 includes a second inductor LS2 and a second capacitor CS2 coupled in parallel through the second wire 150 between the second terminal TR2 and the second power voltage VDD2.

As illustrated in FIG. 2, the first inductor LS1 includes a first coil 240 and the second inductor LS2 includes a second coil 250. Since the first source degeneration circuit 160 and the second source degeneration circuit 170 are disposed symmetrically at the two sides of the axis A, the first coil 240 and the second coil 250 are preferably wired in opposite directions with the same number of loops. In the example in FIG. 2, the first coil 240 is wired in a counterclockwise direction and the second coil 250 is wired in a clockwise direction. Both of the first coil 240 and the second coil 250 have the structure of two loops.

In the configuration described above, the inductor circuit 110 is main oscillating inductor used to oscillate with the capacitor circuit 130 such that the inductor circuit 110 and the capacitor circuit 130 together determine the oscillating frequency. The cross-coupled transistor circuit 120 provides a negative resistance required by the oscillating behavior. The first source degeneration circuit 160 and the second source degeneration circuit 170 are configured to oscillate to lower the phase noise. In an embodiment, when the oscillating frequency of the inductor circuit 110 is F, the first source degeneration circuit 140 and the second source degeneration circuit 170 are preferably to have the oscillating frequency of 2F.

By using the first wire 140 and the second wire 150 traversing the central area of the inductor coil 210 along the axis A and disposing the first source degeneration circuit 160 and the second source degeneration circuit 170 symmetrically at two sides of the axis A to be electrically coupled to the cross-coupled CMOS circuit 130, the symmetry of the electromagnetic field of the oscillator circuit 100 can be maintained. The ability of the first source degeneration circuit 160 and the second source degeneration circuit 170 to lower the phase noise is degraded due to the asymmetrical configuration.

In an embodiment, in order to accomplish the symmetrical configuration, the first wire 140 and the second wire 150 are disposed at different metal layers (not illustrated in the figure) and are overlapped with each other. In another embodiment, the first wire 140 and the second wire 150 are disposed at a same metal layer (not illustrated in the figure) and are parallel to each other.

It is appreciated that the embodiments described above are merely an example. In other embodiments, it should be appreciated that many modifications and changes may be made by those of ordinary skill in the art without departing, from the spirit of the disclosure.

In summary, the present invention discloses the oscillator circuit having phase-noise decreasing mechanism that disposes a first wire and a second wire traversing a central area of an inductor coil in an inductor circuit and disposes a first source degeneration circuit and a second source degeneration circuit in a symmetrical way to be electrically coupled to a cross-coupled CMOS circuit through the first wire and the second wire. Such a configuration maintains a symmetrical electromagnetic field of the oscillator circuit and prevents the ability of the first source degeneration circuit and the second source degeneration circuit to lower the phase noise from degrading.

The aforementioned descriptions represent merely the preferred embodiments of the present invention, without any intention to limit the scope of the present invention thereto. Various equivalent changes, alterations, or modifications based on the claims of present invention are all consequently viewed as being embraced by the scope of the present invention.

What is claimed is:

1. An oscillator circuit having phase-noise decreasing mechanism, comprising:
an inductor circuit comprising an inductor coil surrounding a central area, wherein the inductor coil is electrically coupled between a pair of oscillating output terminals;
a capacitor circuit electrically coupled between the oscillating output terminals;
a cross-coupled CMOS circuit disposed at a first side of the inductor coil and between the inductor coil and the capacitor circuit to be electrically coupled to the pair of oscillating output terminals;
a first wire and a second wire stretching from the first side of the inductor coil along with an axis and traversing the central area to a second side of the inductor coil opposite to the first side to divide the central area into two sub areas that are substantially symmetrical; and
a first source degeneration circuit and a second source degeneration circuit disposed at the second side of the inductor coil and at two symmetrical positions at two sides of the axis;
wherein the first source degeneration circuit is electrically coupled to the first wire and is further electrically coupled to the cross-coupled CMOS circuit through a first terminal, and the second source degeneration circuit is electrically coupled to the second wire and is further electrically coupled to the cross-coupled CMOS circuit through a second terminal.

2. The oscillator circuit of claim 1, wherein the first source degeneration circuit
comprises a first inductor and a first capacitor coupled in series through the first wire and between the first terminal and a first power voltage, the first inductor comprising a first coil; and
the second source degeneration circuit comprises a second inductor and a second capacitor coupled in series through the second wire and between the second terminal and a second power voltage, the second inductor comprising a second coil.

3. The oscillator circuit of claim 2, wherein the oscillator circuit operates according a to
a voltage difference between the first power voltage and the second power voltage.

4. The oscillator circuit of claim 1, wherein the cross-coupled CMOS circuit comprises
a cross-coupled P-type transistor circuit comprising:
a first P-type transistor having a first drain electrically coupled to a first oscillating output terminal of the oscillating output terminals and a first source electrically coupled to the first terminal; and
a second P-type transistor having a second drain electrically coupled to a second oscillating output terminal of the oscillating output terminals and a second source electrically coupled to the first terminal;
wherein a first gate of the first P-type transistor is electrically coupled to the second oscillating output terminal and a second gate of the second P-type transistor is electrically coupled to the first oscillating output terminal.

5. The oscillator circuit of claim 1, wherein the cross-coupled CMOS circuit comprises a cross-coupled N-type transistor circuit comprising:
a first N-type transistor having a first drain electrically coupled to a first oscillating output terminal of the oscillating output terminals and a first source electrically coupled to the second terminal; and
a second N-type transistor having a second drain electrically coupled to a second oscillating output terminal of the oscillating output terminals and a second source electrically coupled to the second terminal;
wherein a first gate of the first N-type transistor is electrically coupled to the second oscillating output terminal and a second gate of the second N-type transistor is electrically coupled to the first oscillating output terminal.

6. The oscillator circuit of claim 1, wherein the first wire and the second wire are disposed at different metal layers and are overlapped with each other.

7. The oscillator circuit of claim 1, wherein the first wire and the second wire are disposed at a same metal layer and are parallel to each other.

8. The oscillator circuit of claim 1, wherein the inductor coil is electrically coupled to the capacitor circuit and the cross-coupled CMOS circuit through the oscillating output terminals by using two extended wires extending towards the first side of the inductor coil.

9. The oscillator circuit of claim 1, wherein the capacitor circuit is a switch capacitor array or a plurality of voltage-controlled capacitors and selectively comprises an output buffer circuit.

10. The oscillator circuit of claim 9, wherein the capacitor circuit comprises at least one metal-oxide-metal capacitor (MOMCAP).
